(19) United States
(12) Patent Application Publication
(10) Pub. No.: US 2024/0296263 A1
(43) Pub. Date: Sep. 5, 2024

(54) METHOD AND SYSTEM FOR IDENTIFYING A KINEMATIC CAPABILITY IN A VIRTUAL KINEMATIC DEVICE

(71) Applicant: Siemens Industry Software Ltd., Tel Aviv (IL)

(72) Inventors: Rahav Madvil, Rishon Lezion (IL); Ori Gadot, Petah Tikva (IL); Joseph Gleyzer, Petah Tikva (IL); Michael Stanin, Sofia (BG)

(21) Appl. No.: 18/571,348

(22) PCT Filed: Jun. 18, 2021
(86) PCT No.: PCT/IB2021/055391

§ 371 Date: Dec. 18, 2023

(51) Int. Cl. G06F 30/27; G06F 30/23

(52) U.S. Cl. CPC G06F 30/27; G06F 30/23

(57) ABSTRACT

A kinematic capability in a virtual kinematic device is identified. Input data are received in the form of data on at least two 2D virtual representations of a given virtual kinematic device. A kinematic analyzer is applied to the input data. The analyzer is modeled with a function trained by a machine learning (ML) algorithm and the kinematic analyzer generates output data. The output data includes data on a set of kinematic descriptors of at least one kinematic capability identified on the at least two 2D virtual representations of the given virtual kinematic device. The at least one identified kinematic capability of the given virtual kinematic device is determined from the output data.

### TECHNICAL FIELD

The present disclosure is directed, in general, to computer-aided design, visualization, and manufacturing (“CAD”) systems, product lifecycle management (“PLM”) systems, product data management (“PDM”) systems, production environment simulation, and similar systems, that manage data for products and other items (collectively, “Product Data Management” systems or PDM systems). More specifically, the disclosure is directed to production environment simulation.

### BACKGROUND OF THE DISCLOSURE

In manufacturing plant design, three-dimensional (“3D”) digital models of manufacturing assets are used for a variety of manufacturing planning purposes. Examples of such usages includes, but are not limited by, manufacturing process analysis, manufacturing process simulation, equipment collision checks and virtual commissioning.

As used herein the terms manufacturing assets and devices denote any resource, machinery, part and/or any other object present in the manufacturing lines.

Process planners are typically required during the phase of 3D digital modeling of the assets of the plant lines.

While digitally planning the production processes of manufacturing lines, the manufacturing simulation planners need to insert into the virtual scene a large variety of devices that are part of the production lines. Examples of plant devices include, but are not limited by, industrial robots and their tools, transportation assets like e.g. conveyors, turn tables, safety assets like e.g. fences, gates, automation assets like e.g. clamps, grippers, fixtures that grasp parts and more.

Some of these devices are kinematic devices with one or more kinematic capabilities which require a kinematic definition via kinematic descriptors of the kinematic chains. The kinematic device definitions enable to simulate, in the virtual environment, the kinematic motions of the kinematic device chains. An example of kinematic device is a clamp which opens its fingers before grasping a part and which closes such fingers for having a stable grasp of the part. For a simple clamp with two rigid fingers, the kinematics definition typically consists in assigning two inks descriptors to the two fingers and a joint descriptor to their mutual rotation axis positioned through their links node. As known in the art of kinematic chain definition, a joint is defined as a connection between two or more links at their nodes, which allows some motion, or potential motion, between the connected links. The following presents simplified definitions of terminology in order to provide a basic understanding of some aspects described herein. As used herein, a kinematic device may denote a device having a plurality of kinematic capabilities defined by a chain, whereby each kinematic capability is defined by descriptors describing a set of links and a set of joints of the chain. In other words, a kinematics descriptor may provide a full or a partial kinematic definition of a kinematic capability of a kinematic device.

Although there are many ready 3D CAD device libraries that can be used by planners, most of these 3D CAD models lack a kinematics definition. Therefore, simulation planners are usually required to manually define the kinematics of these 3D device models, a task which is time consuming, especially with manufacturing plants with a large number of kinematic devices like for example with automotive plants.

In fact, in the field of automotive, OEMs often need to manufacture new car models and variants with frequent modifications and in an automotive plant, in order to manufacture the various parts of a single car model, hundreds kinematic devices are required. Examples of kinematic device include, but are not limited by, robots, fixtures, grippers, clamps, turn tables, etc.

FIG. 2 schematically illustrates a 3D model of a fixture which is used as work-holding device in manufacturing plants. In the fixture 201, dozens of clamps 202 are shown, whereby each clamp is a kinematic device having on or more kinematic chains with kinematic capabilities.

The geometries of the kinematic devices are typically modeled in a CAD software tool and when, each CAD model is loaded into the simulation environment, its kinematic definition needs to be added. Once the kinematics definition is added, the digital kinematic devices are stored in a resource library, which typically allows reutilization of the kinematics models.

However, in automotive, since some of the car parts do vary for different car variants and or different car models, the resource kinematics need to be added for the kinematic devices involved in the manufacturing lines of the different parts of each new car variant or of new car model.

Simulation engineers are assigned the task to maintain the resource library with thousands of kinematic devices and to model in the virtual device representation the required missing kinematics by adding corresponding kinematics descriptors.

Typically, simulation engineers use their professional experience to understand the kinematics functioning of each kinematic device and are therefore capable of creating and adding, into each of device model, its corresponding kinematics definition by identifying chains with links and joints and by providing their descriptors.

FIG. 3 schematically illustrates a block diagram of a typical manual analysis of the kinematics capability of a virtual clamp model (Prior Art).

The simulation engineer 303 analyzes the kinematic capability of a CAD model 301 of a simple clamp, whereby the CAD model is lacking a kinematic definition. She loads into the virtual environment the clamp model 301 and with her analysis she identifies the two links Ink1, Ink2 and the joint j1 of the clamp's chain in order to build a kinematic clamp model 303 via a kinematics editor 304 comprising kinematic descriptors of the links Ink1, Ink2 and the joint j1. It is noted that the exemplified kinematic clamp model 302 is a simple clamp having only two links Ink1, Ink2 and a single rotation joint j1. The skilled in the art knows that there are clamps with more than one chain and joints and that there several other types of joints. Examples of kinematic joint types include, but are not limited by, prismatic joints, revolute or rotational joints, helical joints, spherical joints and planar joints.

The clamp model 301 without kinematics may be defined in a CAD file format. The clamp model 303 with kinematics descriptors may be preferably defined in a file format allowing CAD geometry together with kinematics definition as for example jt format files with both geometry and kinematics (which are usually stored in a cojt folder) for the Process Simulate platform, or for example .prt format files for the NX platform, or any other kinematics object file formats which can be used by an industrial motion simulation software, e.g. a Computer Aided Robotic (“CAR”) tool like for example Process Simulate of the Siemens Digital Industries Software group.

As above explained, creating and maintaining definitions of kinematics capabilities and chain descriptors for a large variety of kinematic devices is a tedious, repetitive and time-consuming task and requires the skills of experienced users.

Improved techniques for identifying a kinematic capability in a virtual kinematic device are therefore desirable.

### SUMMARY OF THE DISCLOSURE

Various disclosed embodiments include methods, systems, and computer readable mediums for identifying a kinematic capability in a virtual kinematic device, wherein a virtual kinematic device is a virtual device having at least one kinematic capability and wherein a kinematic capability is defined by a chain with a joint connecting at least two links of the virtual device. A method includes receiving input data; wherein input data comprise data on at least two 2D virtual representations of a given virtual kinematic device. The method further includes applying a kinematic analyzer to the input data; wherein the kinematic analyzer is modeled with a function trained by a ML algorithm and the kinematic analyzer generates output data. The method further includes providing output data; wherein the output data comprises data on a set of kinematic descriptors of at least one kinematic capability identified on the at least two 2D virtual representations of the given virtual kinematic device. The method further includes determining from the output data the at least one identified kinematic capability in the given virtual kinematic device.

Various disclosed embodiments include methods, systems, and computer readable mediums for providing a trained function for identifying a kinematic capability in a virtual kinematic device, wherein a kinematic device is a device having at least one kinematic capability and wherein a kinematic capability is defined by a joint connecting at least two links of the kinematic device. A method includes receiving input training data; wherein the input training data comprises data on a plurality of at least two 2D virtual representations of a plurality of virtual kinematic devices. The method further includes receiving output training data; wherein the output training data comprise, for each of the plurality of virtual kinematic devices, data on a set of kinematic descriptors on a set of kinematic capabilities of the at least two 2D virtual representations of each of the plurality of kinematic devices; wherein the output training data is related to the input training data. The method further includes training a function based on the input training data and the output training data via a ML algorithm. The method further includes providing the trained function for modeling a kinematic analyzer.

Various disclosed embodiments include methods, systems, and computer readable mediums for detecting a kinematic capability in a virtual kinematic device, wherein a virtual kinematic device is a virtual device having at least one kinematic capability and wherein a kinematic capability is defined by a chain with a joint connecting at least two links of the virtual device. A method includes receiving input training data; wherein the input training data comprises data on a plurality of at least two 2D virtual representations of a plurality of virtual kinematic devices. The method further includes receiving output training data; wherein the output training data comprise, for each of the plurality of virtual kinematic devices, data on a set of kinematic descriptors on a set of kinematic capabilities of the at least two 2D virtual representations of each of the plurality of kinematic devices; wherein the output training data is related to the input training data. The method further includes training a function based on the input training data and the output training data via a ML algorithm. The method further includes providing the trained function for modeling a kinematic analyzer. The method further includes receiving input data; wherein input data comprise data on at least two 2D virtual representations of a given virtual kinematic device. The method further includes applying the kinematic analyzer to the input data; wherein the kinematic analyzer is modeled with the function trained by a ML algorithm and the kinematic analyzer generates output data. The method further includes providing output data; wherein the output data comprises data on a set of kinematic descriptors of at least one kinematic capability identified on the at least two 2D virtual representations of the given virtual kinematic device. The method further includes determining from the output data the at least one identified kinematic capability in the given virtual kinematic device.

The foregoing has outlined rather broadly the features and technical advantages of the present disclosure so that those skilled in the art may better understand the detailed description that follows. Additional features and advantages of the disclosure will be described hereinafter that form the subject of the claims. Those skilled in the art will appreciate that they may readily use the conception and the specific embodiment disclosed as a basis for modifying or designing other structures for carrying out the same purposes of the present disclosure. Those skilled in the art will also realize that such equivalent constructions do not depart from the spirit and scope of the disclosure in its broadest form.

Before undertaking the DETAILED DESCRIPTION below, it may be advantageous to set forth definitions of certain words or phrases used throughout this patent document: the terms “include” and “comprise,” as well as derivatives thereof, mean inclusion without limitation; the term “or” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects, and in which:

FIG. 1 illustrates a block diagram of a data processing system in which an embodiment can be implemented.

FIG. 2 schematically illustrates a 3D model of a fixture.

FIG. 3 schematically illustrates a block diagram of a typical manual analysis of the kinematics capability of a virtual clamp model (Prior Art).

FIG. 4A schematically illustrates a block diagram for training a function with a Machine Learning (“ML”) algorithm for identifying a kinematic capability in a virtual kinematic device in accordance with disclosed embodiments.

FIG. 4B schematically illustrates exemplary input training data for training a function with a ML algorithm in accordance with disclosed embodiments.

FIG. 4C schematically illustrates exemplary output training data for training a function with a ML algorithm in accordance with disclosed embodiments.

FIG. 4D schematically illustrates orthogonal views of the clamp of FIG. 4B with bounding boxes from FIG. 4C.

FIG. 5 schematically illustrates a block diagram for identifying a kinematic capability in a virtual kinematic device in accordance with disclosed embodiments.

FIG. 6 illustrates a flowchart for identifying a kinematic capability in a virtual kinematic device in accordance with disclosed embodiments.

### DETAILED DESCRIPTION

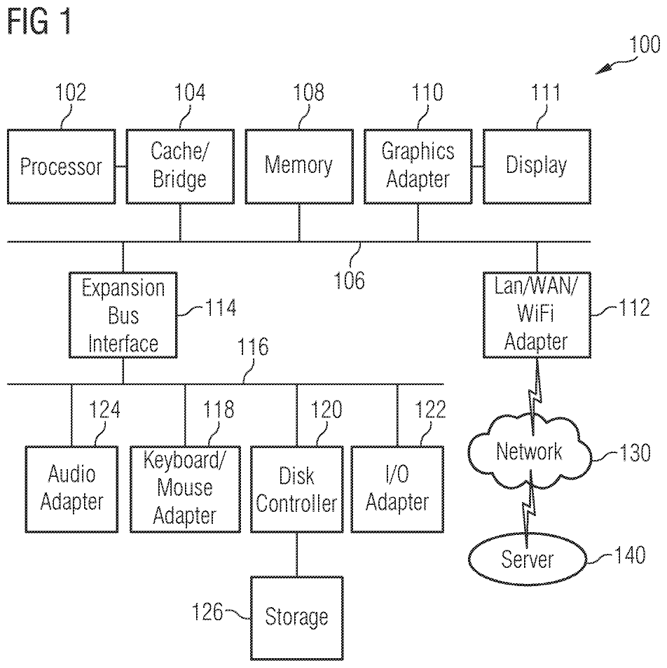

FIGS. 1 through 6, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device. The numerous innovative teachings of the present application will be described with reference to exemplary non-limiting embodiments.

Furthermore, in the following the solution according to the embodiments is described with respect to methods and systems for identifying a kinematic capability in a virtual kinematic device as well as with respect to methods and systems for providing a trained function for identifying a kinematic capability in a virtual kinematic device.

Features, advantages, or alternative embodiments herein can be assigned to the other claimed objects and vice versa.

In other words, claims for methods and systems for providing a trained function for identifying a kinematic capability in a virtual kinematic device can be improved with features described or claimed in context of the methods and systems for identifying a kinematic capability in a virtual kinematic device and vice versa. In particular, the trained function of the methods and systems for detecting a false error in a set of errors detected on components of a board inspected by an AOI machine can be adapted by the methods and systems for identifying a kinematic capability in a virtual kinematic device. Furthermore, the input data can comprise advantageous features and embodiments of the training input data, and vice versa. Furthermore, the output data can comprise advantageous features and embodiments of the output training data, and vice versa.

Previous techniques did not enable efficient kinematics capability identification in a virtual kinematic device. The embodiments disclosed herein provide numerous technical benefits, including but not limited to the following examples.

Embodiments enable to automatically identify and to automatically define kinematic capabilities of virtual kinematic devices.

Embodiments enable to identify and to define the kinematic capabilities of virtual kinematic devices in a fast and efficient manner.

Embodiments minimizes the need of trained users for identifying kinematic capabilities of kinematic devices and reduce engineering time. Embodiments minimizes the quantity of “human errors” in defining the kinematic capabilities of virtual kinematic devices.

Embodiments may advantageously be used for a large variety of different types of kinematics devices.

Embodiments enable to automatically detect in a kinematic device the presence of joint(s) and to generate their descriptors, for example their axis(es) or other relevant graphic objects, on the two-dimensional (“2D”) virtual representations of the device.

FIG. 1 illustrates a block diagram of a data processing system 100 in which an embodiment can be implemented, for example as a PDM system particularly configured by software or otherwise to perform the processes as described herein, and in particular as each one of a plurality of interconnected and communicating systems as described herein. The data processing system 100 illustrated can include a processor 102 connected to a level two cache/bridge 104, which is connected in turn to a local system bus 106. Local system bus 106 may be, for example, a peripheral component interconnect (PCI) architecture bus. Also connected to local system bus in the illustrated example are a main memory 108 and a graphics adapter 110. The graphics adapter 110 may be connected to display 111.

Other peripherals, such as local area network (LAN)/Wide Area Network/Wireless (e.g. WiFi) adapter 112, may also be connected to local system bus 106. Expansion bus interface 114 connects local system bus 106 to input/output (I/O) bus 116. I/O bus 116 is connected to keyboard/mouse adapter 118, disk controller 120, and I/O adapter 122. Disk controller 120 can be connected to a storage 126, which can be any suitable machine usable or machine readable storage medium, including but are not limited to nonvolatile, hard-coded type mediums such as read only memories (ROMs) or erasable, electrically programmable read only memories (EEPROMs), magnetic tape storage, and user-recordable type mediums such as floppy disks, hard disk drives and compact disk read only memories (CD-ROMs) or digital versatile disks (DVDs), and other known optical, electrical, or magnetic storage devices.

Also connected to I/O bus 116 in the example shown is audio adapter 124, to which speakers (not shown) may be connected for playing sounds. Keyboard/mouse adapter 118 provides a connection for a pointing device (not shown), such as a mouse, trackball, trackpointer, touchscreen, etc.

Those of ordinary skill in the art will appreciate that the hardware illustrated in FIG. 1 may vary for particular implementations. For example, other peripheral devices, such as an optical disk drive and the like, also may be used in addition or in place of the hardware illustrated. The illustrated example is provided for the purpose of explanation only and is not meant to imply architectural limitations with respect to the present disclosure.

A data processing system in accordance with an embodiment of the present disclosure can include an operating system employing a graphical user interface. The operating system permits multiple display windows to be presented in the graphical user interface simultaneously, with each display window providing an interface to a different application or to a different instance of the same application. A cursor in the graphical user interface may be manipulated by a user through the pointing device. The position of the cursor may be changed and/or an event, such as clicking a mouse button, generated to actuate a desired response.

One of various commercial operating systems, such as a version of Microsoft Windows™, a product of Microsoft Corporation located in Redmond, Wash. may be employed if suitably modified. The operating system is modified or created in accordance with the present disclosure as described.

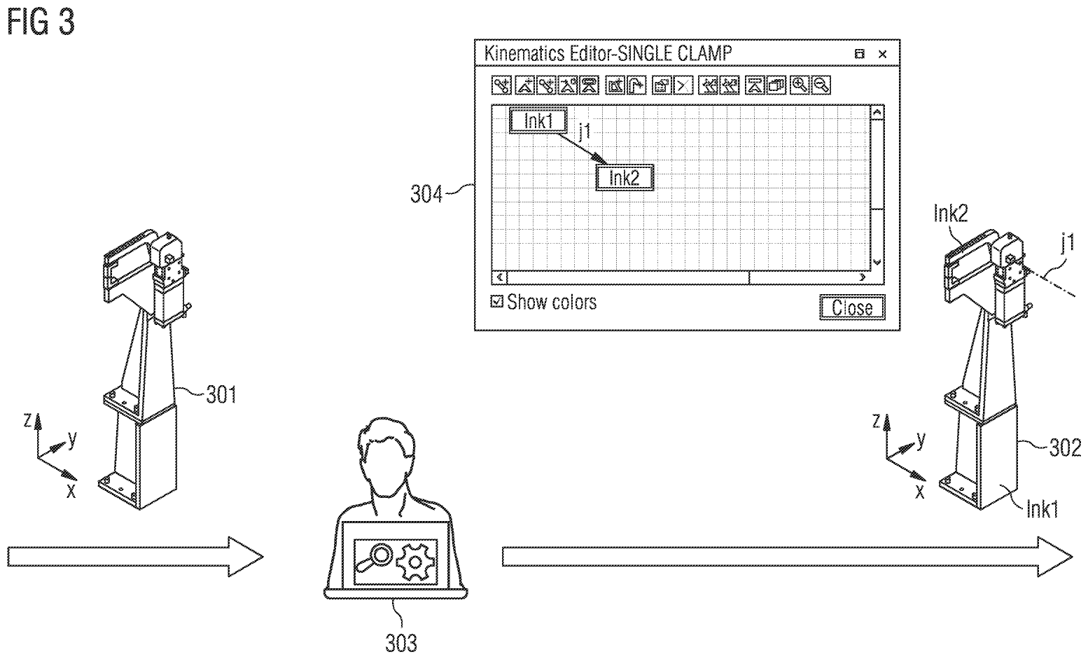

LAN/WAN/Wireless adapter 112 can be connected to a network 130 (not a part of data processing system 100), which can be any public or private data processing system network or combination of networks, as known to those of skill in the art, including the Internet. Data processing system 100 can communicate over network 130 with server system 140, which is also not part of data processing system 100, but can be implemented, for example, as a separate data processing system 100. FIG. 3 schematically illustrates a block diagram for training a function with a ML algorithm for modeling a false error detector in accordance with disclosed embodiments.

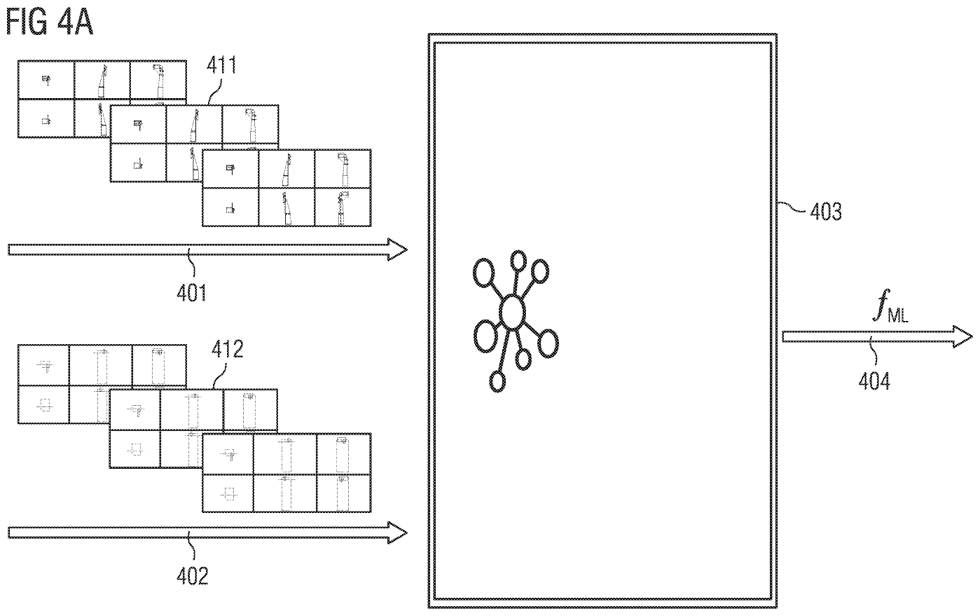

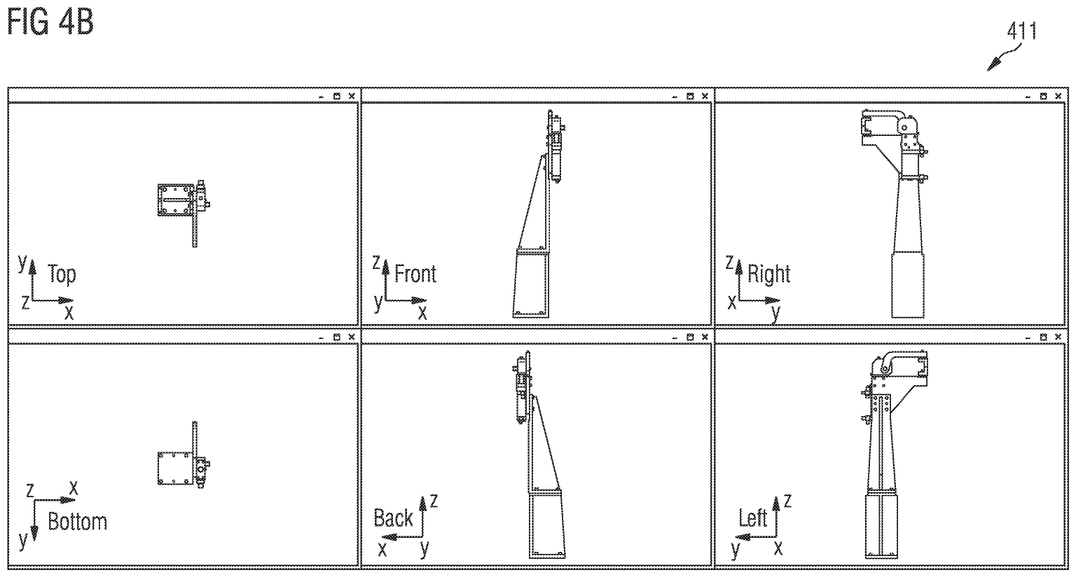

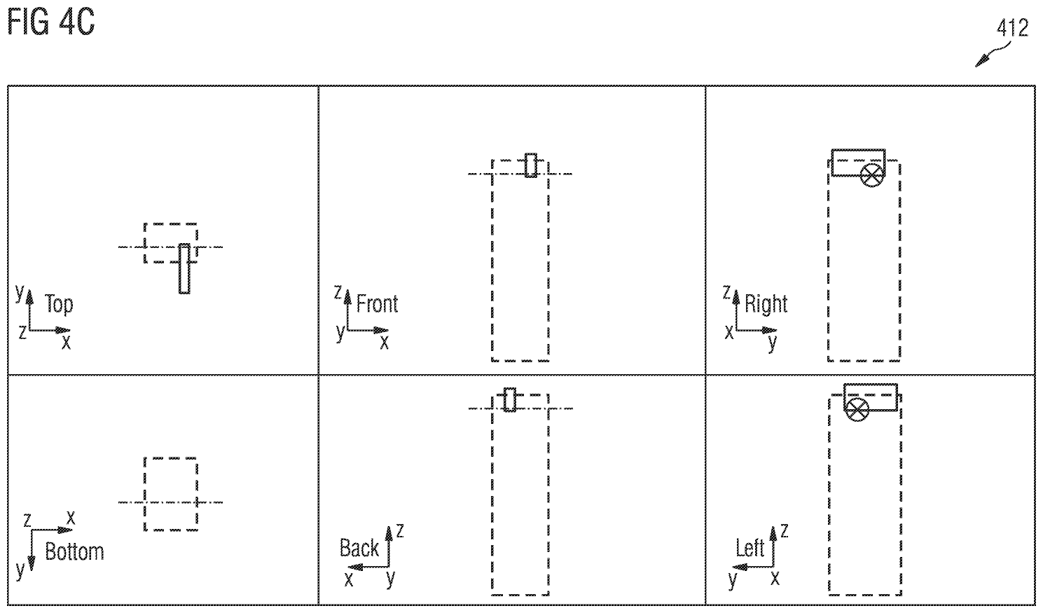

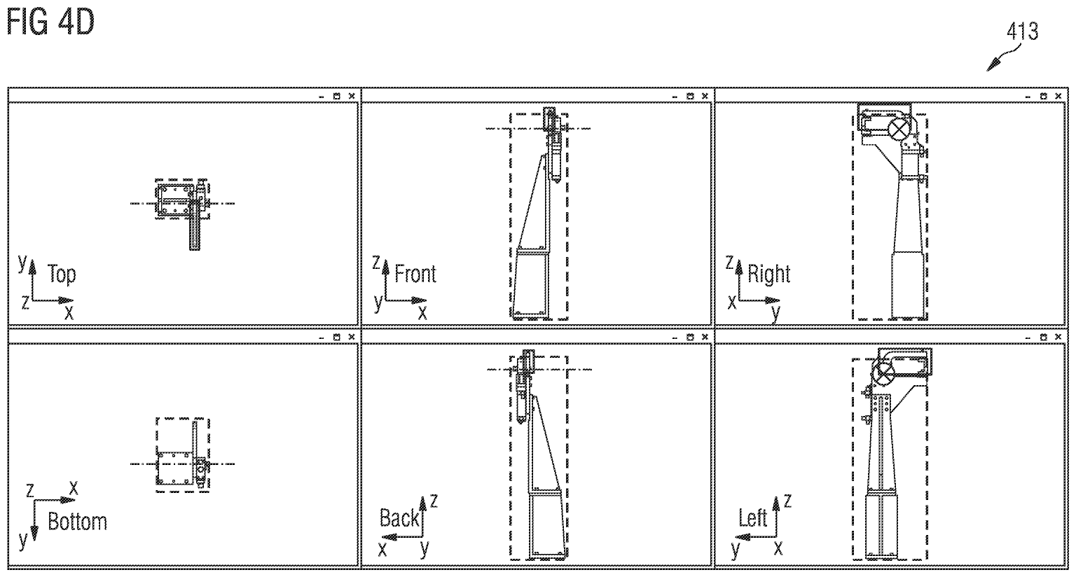

FIG. 4A schematically illustrates a block diagram for training a function with a ML algorithm for identifying a kinematic capability in a virtual kinematic device in accordance with disclosed embodiments.

During the ML training phase, input training data 401 may be generated by getting at least two 2D virtual representations—e.g. in form of images or drawings—from a 3D model of a kinematic device, herein exemplified with a simple clamp. The 2D images are preferably two or more orthogonal projections of the 3D model of the virtual device.

FIG. 4B schematically illustrates exemplary input training data for training a function with a ML algorithm in accordance with disclosed embodiments. In FIG. 4B are shown six 2D orthographic views 411 of the clamp, e.g. top, bottom, front, back, right, left.

The output training data are obtained by getting, for each 2D image, kinematic descriptors defining the chain elements—e.g. links, joints—of the one or more kinematic capabilities of the device as exemplified in FIG. 4C.

In embodiments, the kinematic descriptors are describing the set of links of the 2D images and are describing the position of one or more joints for example by defining an additional graphic object like an axis in some images (see, in FIG. 4D, the dotted dashed line in the top, bottom, front, back views) or like a point or a cross or a very small square (not shown) in other orthogonal images (see, in FIG. 4D, the cross in the right and left views).

In embodiments, links and axis descriptors can comprise labels with or without bounding boxes or can comprise bounding boxes with or without labels.

In embodiments, the output training data may automatically be generated as labeled training dataset departing from the kinematic file of the device model. In other embodiments, output training data are manually generated by defining and labeling each link and joint with descriptor(s). In other embodiments, a mix of automatic and manual labeled dataset may advantageously be used.

In embodiments, the 2D images used for data training the ML algorithm and/or for execution of the algorithm contain grayscale or RGB color information.

FIG. 4C schematically illustrates exemplary output training data for training a function with a ML algorithm in accordance with disclosed embodiments. In FIG. 4C are shown examples of descriptors of the kinematics capabilities of the device for all six projections 412.

Such descriptors can be for example provided in form of metadata with coordinates data on the corners of the bounding boxes or in form of images, e.g. like bounding boxes or other graphic objects.

FIG. 4C shows the bounding boxes of the two links, in particular a bigger dashed bounding box for the first link Ink1, a smaller dashed bounding box for the second link Ink2 and the dashed-dotted line or the cross for the rotational joint j1.

FIG. 4D schematically illustrates orthogonal views of the clamp of FIG. 4B with bounding boxes from FIG. 4C in accordance with embodiments. The six images of FIG. 4D are obtainable as juxtaposition of the six images FIG. 4B and the six images of FIG. 4B. FIG. 4D clarifies the meaning of the bounding boxes and descriptors used in FIG. 4C. In other embodiments, the images of FIG. 4D may be used as output training data.

In embodiments, the input training data, e.g. data with the 2D representations of each device, are obtainable by data of the 3D models of the devices like for example CAD files, .jt, .prt, .asm, .par, .sldprt, .sldasm format files etc.

In embodiments, the output training data, e.g. data with the kinematics descriptors of the 2D representations of each device, are obtainable from kinematic files like jt. files for example from their kinematics metadata forming cojt. folders or other kinematics format data files.

In embodiments, a pre-trained neural network may be used and its capabilities are refined, for example like the Common Objects in Context (“COCO”) dataset.

A dataset for training the neural network may automatically be generated. For example, in embodiments, a large number of kinematic device model files with kinematics capability definitions might be used for ML training purposes.

Assume, in an exemplary embodiment, that hundreds jt. files with kinematics information are used for training purposes. For example, a cojt. folder may contain the geometry in a jt. format and the kinematics description information as metadata e.g. in a xml file.

In this exemplary embodiment, each cojt. folder file is loaded separately to the Process Simulate CAR tool. From the CAR tool, 2D images are extracted from the six main directions, e.g. six images taken from e.g. top, bottom, front, back, right, left respectively the +z, ty, +x, directions, as exemplified in FIG. 4B. Such extracted 2D images are then used as input training data. As output training data, metadata on labels and/or bounding boxes may advantageously be generated from the kinematics information included in the cojt. folder. The kinematic information may for example be used to tag the links and joints by specifying their bounding boxes as exemplified in FIG. 4C and in FIG. 4D.

In embodiments, the links and joints of the device images are preferably tagged in an automatic manner.

In embodiments, joints are introduced as graphic object and are defined as axes, points, crosses, collapsed squares, small squares and small circles or other graphical object suitable to represent a joint.

In embodiments of the ML training phase, the input training data 401 for training the neural network are the 2D virtual representations of the kinematic devices 411 generated from the 3D model files and the output training data 402 are the labeled data 412 of the kinematics chain elements (e.g. links and joints) which are for example obtainable from the kinematic object files.

In embodiments, the result of the training process 403 is a trained neural network 404 capable of automatically detecting descriptors of kinematic links and joints from a given set of 2D images.

In embodiments, the trained neural network herein called “kinematic analyzer” is capable of detecting bounding boxes of links and joints and/or other relevant graphic objects describing a kinematic chain.

In embodiments, the labeled observation data set is divided in a training set and a test set; the ML algorithm is fed with the training set and the prediction model receives inputs from the machine learner and from the test set to output statistics.

In embodiments, circa 70% of the dataset may be used as training dataset for the calibration of the weights of the neural network, circa 20% of the dataset may be used as validation dataset for control and monitor of the current training process and modify the training process if needed, and circa 10% of the dataset may be used later as test set, after the training and validation is done, for evaluating the accuracy of the ML algorithm.

In embodiments, the entire data preparation for the ML training procedure may be done automatically by a software application.

In embodiments, the output training data are automatically generated from the kinematics object files or from manual kinematics labelling or any combination thereof. In embodiments, the output training data are provided as metadata, text data, image data and/or any combination thereof.

In embodiments, the input/output training data comprise data in numerical format, in text format, in image format, in other format and/or in any combination thereof.

In embodiments, during the training phase, the ML algorithm learns to detect kinematic links and joints of device by “looking” at the 2D device images from several main viewpoints. In embodiments, the number of image view points may preferably be between two to six. In other embodiments, a higher number of image viewpoints may be used.

In embodiments, the input training data and the output training data may be generated from a plurality of models of similar or different virtual kinematic devices.

Embodiments include a method and a system for providing a trained function for identifying a kinematic capability in a virtual kinematic device, wherein a kinematic device is a device having at least one kinematic capability and wherein a kinematic capability is defined by a joint connecting at least two links of the kinematic device.

Embodiments further comprise the following steps:
receiving input training data; wherein the input training data comprises data on a plurality of at least two 2D virtual representations of a plurality of virtual kinematic devices;
receiving output training data; wherein the output training data comprise, for each of the plurality of virtual kinematic devices, data on a set of kinematic descriptors on a set of kinematic capabilities of the at least two 2D virtual representations of each of the plurality of kinematic devices; wherein the output training data is related to the input training data;
training a function based on the input training data and the output training data via a ML algorithm;
providing the trained function for modeling a kinematic analyzer.

In embodiments, the input training data are generated by extracting 2D images from CAD files.

In embodiments, the output training data are generated from the 2D images by labeling a set of links—e.g. via graphic link objects—and by generating a set of joint axes—e.g. via graphic joint objects.

In embodiments, the virtual kinematic devices belong to the same device class (e.g. clamp, grip, fixture, turn table classes, generic ones or of a specific vendor) or belong to a family of device classes (e.g. clamps with a predetermined shape of all vendors).

In embodiments, during the training phase with training data, the trained function can adapt to new circumstances and to detect and extrapolate patterns.

In general, parameters of a trained function can be adapted by means of training. In particular, supervised training, semi-supervised training, unsupervised training, reinforcement learning and/or active learning can be used. Furthermore, representation learning (an alternative term is “feature learning”) can be used. In particular, the parameters of the trained functions can be adapted iteratively by several steps of training.

In particular, a trained function can comprise a neural network, a support vector machine, a decision tree and/or a Bayesian network, and/or the trained function can be based on k-means clustering, Qlearning, genetic algorithms and/or association rules.

In particular, a neural network can be a deep neural network, a convolutional neural network, or a convolutional deep neural network. Furthermore, a neural network can be an adversarial network, a deep adversarial network and/or a generative adversarial network.

In embodiments, the ML algorithm is a supervised model, for example a binary classifier which is classifying between true and pseudo error. In embodiments, other classifiers may be used for example logistic regressor, random forest classifier, xgboost classifier etc. In embodiments, a feed forward neural network via TensorFlow framework may be used.

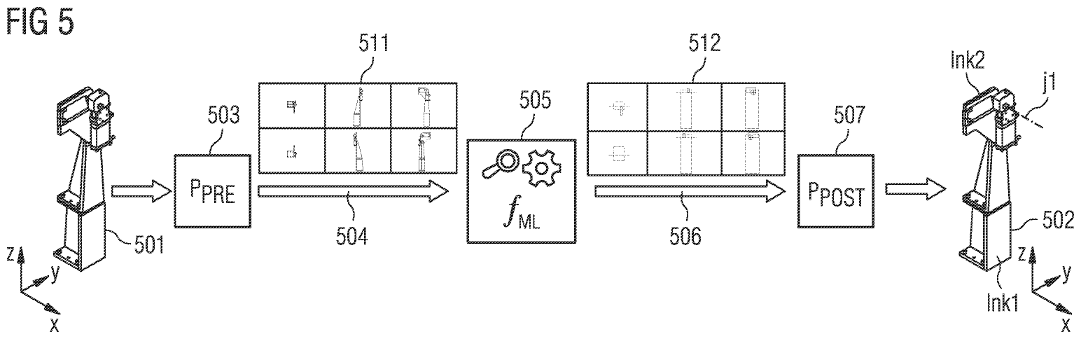

FIG. 5 schematically illustrates a block diagram for identifying a kinematic capability in a virtual kinematic device in accordance with disclosed embodiments.

FIG. 5 schematically shows an example embodiment of neural network execution.

In embodiments, data on a 3D model of a virtual clamp 501 are provided. Such data can be provided in form of a CAD file or a mesh (e.g. an STL file).

In embodiments, the provided data are pre-processed 503 in order to extract two or more 2D images 504 of the clamp, for example six orthogonal projections 511 are automatically extracted. The images may be in greyscale or in color format. The 2D images 504 are applied to a kinematic analyzer 505 which provides outputs data 506. The output data comprises descriptors 512 of the links and of the joint detected in the inputted images of the clamp. In embodiments, the descriptors are provided as bounding boxes information data. The output data 506 are post-processed 507 in order to determine the links Ink1, Ink2 in the 3D model of the clamp and to define the axis of the joint j1. The information on the determined links and the joint may be added as kinematic definition to generate a kinematic file (e.g. in a cojt folder) from the departing CAD file without kinematics (e.g. a .jt file).

In embodiments, the six images extracted from a 3D model file of a new kinematic device are applied to the kinematic analyzer previously trained with a ML algorithm. The output of the kinematic analyzer are descriptors of one or more kinematic capability of the new device.

In embodiments, the kinematic analyzer examines the 2D images taken from two or more viewpoints and is then capable of determining and locating where the joint axes are to be positioned and it is the capable to generate a descriptor of the position of one or more relevant axes of a corresponding kinematic chain having one or more related links. In embodiments, the position of one axis is defined with a descriptor, for example in a format of a bounding box like for example a collapsed bounding box of a line in some view point (e.g. see dotted dash line in FIGS. 4C and 4D) a point or a small square in other orthogonal view points (e.g. see the cross in FIGS. 4C and 4D.

In embodiments, the output data of the kinematic analyzer are the bounding boxes which may for example be represented by pixel coordinates of their corners.

In embodiments, each recognized link entity is labeled with its link identifier such as Ink1, Ink2 etc.

By means of the kinematic analyzer, embodiments enable to automatically determine where are the links and the joint(s) in order to defining them as part of the kinematic chain(s) of the analyzed device.

Embodiments enable to automatically generate the definition of the kinematics capability of the analyzed device.

In embodiments, during the execution phase of the algorithm, a device's CAD file may be provided as input for pre-processing 503.

In embodiments, the file of the CAD model can be provided in a jt. format file, e.g. the native format of Process Simulate. In other embodiments, the file describing the device model can be provided into any other suitable file format describing a 3D model or sub-elements of it. In embodiments, this file in this latter format may preferably be converted into JT via a file converter, e.g. an existing one or ad-hoc created converter.

In embodiments, from the CAD model several 2D images of the images from different directions 511 are automatically extracted by a pre-processing module 503 so that they can be fed 504 into the trained neural network 505.

In embodiments, the output 606 of the kinematic analyzer 505 algorithm provide a set of descriptors of the joints and links 512 in all the images for determining 507 links and joint(s) of the kinematic chain(s) in the device 3D model 502.

In embodiments, a joint entity is identified via a set of graphic joint objects or corresponding metadata even when such graphic joint objects are not present in the 2D image input data of the kinematic analyzer.

In embodiments, the output of the kinematic analyzer with descriptors of the joints and link(s) 512 is processed by a post-processing module 507.

In embodiments, the post processing module 507 makes use of the descriptors of the links, e.g. the bounding boxes of the links in the 2D images, to classify each corresponding 3D geometry entity with a corresponding link identifier.

In embodiments, in the post processing module 507, a triangulation is executed in order to extract the output data related to the 2D images and defining their corresponding data into the 3D scene.

In embodiments, the post processing module 507 triangulates the joint(s) locations from the 2D coordinates into the 3D scene.

In the simplified exemplary embodiment of FIG. 5, the only detected joint is a rotational joint and a corresponding axis is defined and generated. In embodiments, the joint(s) might be prismatic joints, revolute or rotational joints, helical joints, spherical joints and planar joints.

In embodiments, all joint(s) are well-defined and properly located in the 3D scene.

In embodiments, the generated descriptor(s) of the joint(s), e.g. the joint axis coordinates for this example, are adjusted and fine-tuned to fit the 3D CAD model. For example, if a small deviation is detected, minor adjustments are made so that the axis(es) are parallel or perpendicular to the corresponding underlying geometry.

Embodiments enable to implement automatic error corrections during or after the triangulation phase.

In embodiments, the entire kinematic chain(s) can be compiled and created so to generate an output .jt file with kinematic definitions.

Embodiments have been described for a device being a simple clamp with two links and one joint. In embodiments, clamps may have more than one joints. In embodiments, the device might be any device having at least one kinematic capability and chain.

In embodiments, the kinematic analyzer is a specific device analyzer and is trained and used specifically for a given type of kinematic device, e.g. specifically for certain type(s) of clamps, of grippers or of fixtures.

In other embodiments, the kinematic analyzer is a general device analyzer and is trained and is used to fit a broad family of different type of kinematic devices.

In embodiments, for a kinematic detector for specific device types, a pre-processing classification phase may be performed to classify the type of received kinematic device.

In embodiments, a generic classifier detects which is the specific kinematic analyzer needs to be used, and then the specific analyzer is activated accordingly.

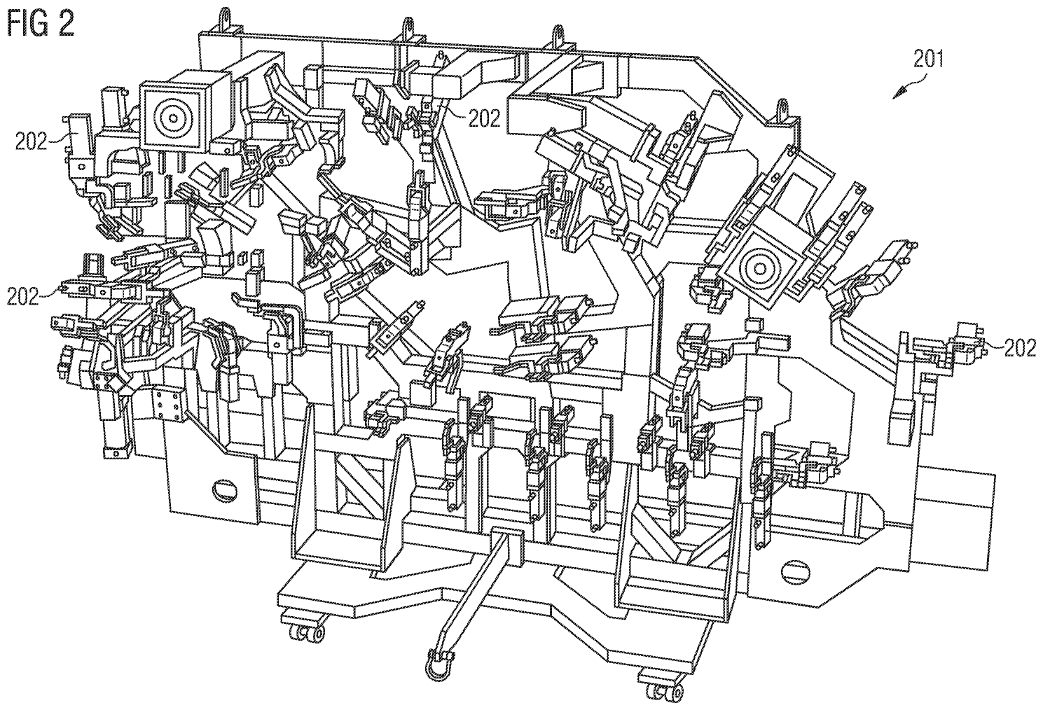

In embodiments, for a complex composite kinematic device—as for example the fixture of FIG. 2 which contains dozens of clamps—the kinematic analysis can be performed by automatically extracting each simpler kinematic device, e.g. each clamp, and then feeding each simpler device automatically into the kinematic analyzer.

In other embodiments, the kinematic analyzer is capable of automatically analyzing composite kinematic devices like for example the fixture of FIG. 2.

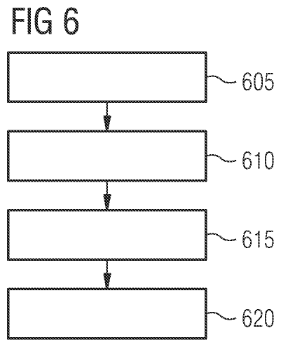

FIG. 6 illustrates a flowchart of a method for identifying a kinematic capability in a virtual kinematic device in accordance with disclosed embodiments. Such method can be performed, for example, by system 100 of FIG. 1 described above, but the “system” in the process below can be any apparatus configured to perform a process as described. The virtual kinematic device is a virtual device having at least one kinematic capability and wherein a kinematic capability is defined by a kinematic chain with a joint connecting at least two links of the virtual device.

At act 605, input data are received. The input data comprise data on at least two 2D virtual representations of a given virtual kinematic device. In embodiments, the 2D virtual representations are 2D images e.g. CAD drawings or 2D representations included or extractable from a CAD model of the virtual kinematic device. In embodiments, the input data is automatically generated from a received 3D geometry file of the device.

At act 610, kinematic analyzer is applied to the input data. The kinematic analyzer is modeled with a function trained by a ML algorithm and the kinematic analyzer generates output data.

At act 615, output data is provided. The output data comprises data on a set of kinematic descriptors of at least one kinematic capability identified on the at least two 2D virtual representations of the given virtual kinematic device.

In embodiments, the set of kinematic descriptors describes a set of graphic objects e.g. bounding boxes of a set of links and of a set of joints of the given kinematic device.

At act 620, it is determined, from the output data, the at least one identified kinematic capability in the given virtual kinematic device. In embodiments, from the output data, the kinematic chain of the virtual device is determined by determining the corresponding links and joint.

In embodiments, the kinematic capability is determined by identifying at least two device's links and by defining the characteristics of the joint associated to the at least two links, this capability can be determined in the 2D drawings or in the 3D model of the virtual kinematic device. In embodiments, the kinematic capability in the 3D space is determined via triangulation. Examples of joint characteristics include, but are not limited by, joint position, joint orientation, joint type, any characteristics of a joint graphic object describing the joint in a graphic way or in a meta-data way.

In embodiments, the characteristics of the defined joint are adjusted according to the geometry of the virtual device for example by positioning the joint axis parallel or perpendicular or at a given angle to selectable set of geometrical features of the links. Examples of set of geometrical links feature include, but are not limited by, surface, sides, axes, basis, views of the link(s) and any other geometry related characteristic of the link.

In embodiments, at least one manufacturing operation performed by the kinematic device is controlled in accordance with the outcomes of a simulation of a set of manufacturing operations performed by the virtual kinematic device in a virtual environment of a computer simulation platform.

In embodiments, the term “receiving”, as used herein, can include retrieving from storage, receiving from another device or process, receiving via an interaction with a user or otherwise.

Those skilled in the art will recognize that, for simplicity and clarity, the full structure and operation of all data processing systems suitable for use with the present disclosure is not being illustrated or described herein. Instead, only so much of a data processing system as is unique to the present disclosure or necessary for an understanding of the present disclosure is illustrated and described. The remainder of the construction and operation of data processing system 100 may conform to any of the various current implementations and practices known in the art.

It is important to note that while the disclosure includes a description in the context of a fully functional system, those skilled in the art will appreciate that at least portions of the present disclosure are capable of being distributed in the form of instructions contained within a machine-usable, computer-usable, or computer-readable medium in any of a variety of forms, and that the present disclosure applies equally regardless of the particular type of instruction or signal bearing medium or storage medium utilized to actually carry out the distribution. Examples of machine usable/readable or computer usable/readable mediums include: nonvolatile, hard-coded type mediums such as read only memories (ROMs) or erasable, electrically programmable read only memories (EEPROMs), and user-recordable type mediums such as floppy disks, hard disk drives and compact disk read only memories (CD-ROMs) or digital versatile disks (DVDs).

Although an exemplary embodiment of the present disclosure has been described in detail, those skilled in the art will understand that various changes, substitutions, variations, and improvements disclosed herein may be made without departing from the spirit and scope of the disclosure in its broadest form.

None of the description in the present application should be read as implying that any particular element, step, or function is an essential element which must be included in the claim scope: the scope of patented subject matter is defined only by the allowed claims.

1-15. (canceled)

16. A method for identifying, by a data processing system, a kinematic capability in a virtual kinematic device, wherein the virtual kinematic device is a virtual device having at least one kinematic capability and wherein a kinematic capability is defined by a chain with a joint connecting at least two links of the virtual device, the method comprising:
receiving input data, the input data including data on at least two 2D virtual representations of a given virtual kinematic device;
applying a kinematic analyzer to the input data, the kinematic analyzer being modeled with a function trained by a machine learning (ML) algorithm and the kinematic analyzer being configured for generating output data;
providing output data, the output data including data on a set of kinematic descriptors of at least one kinematic capability identified on the at least two 2D virtual representations of the given virtual kinematic device; and
determining from the output data the at least one identified kinematic capability in the given virtual kinematic device.

17. The method according to claim 16, wherein the set of kinematic descriptors describes a set of bounding boxes of a set of links and of a set of joints of the given virtual kinematic device.

18. The method according to claim 16, wherein the 2D virtual representations are 2D images extracted from a CAD model of the given virtual kinematic device.

19. The method according to claim 16, which comprises determining the kinematic capability by identifying at least two links of the device and by defining characteristics of a joint associated with the at least two links in a 3D model of the virtual kinematic device.

20. The method according to claim 19, which comprises adjusting the characteristics of the joint according to a geometry of the virtual device.

21. The method according to claim 20, wherein the adjusting step comprises positioning an axis of the joint parallel or perpendicular or at a given angle to a selectable set of geometrical features of the links.

22. The method according to claim 16, further comprising a step of controlling at least one manufacturing operation performed by a kinematic device in accordance with outcomes of a computer-implemented simulation of a corresponding set of virtual manufacturing operations of a corresponding virtual kinematic device.

23. A method for providing, by a data processing system, a trained function for identifying a kinematic capability in a virtual kinematic device, wherein a kinematic device is a device having at least one kinematic capability and wherein a kinematic capability is defined by a joint connecting at least two links of the kinematic device, the method comprising:
receiving input training data, the input training data including data on a plurality of at least two 2D virtual representations of a plurality of virtual kinematic devices;
receiving output training data, the output training data being related to the input training data and including, for each of the plurality of virtual kinematic devices, data on a set of kinematic descriptors on a set of kinematic capabilities of the at least two 2D virtual representations of each of the plurality of kinematic devices;
training a function based on the input training data and the output training data via a machine learning (ML) algorithm; and
providing the trained function for modeling a kinematic analyzer.

24. The method according to claim 23, which comprises generating the input training data by extracting 2D images from CAD files.

25. The method according to claim 23, which comprises generating the output training data from the 2D images by labeling a set of links and by generating a set of joint axes.

26. The method according to claim 23, wherein the virtual kinematic devices belong to the same class or to a family of classes.

27. A data processing system, comprising:
a processor; and
an accessible memory; and
wherein the data processing system is configured to:
receive input data, the input data being data on at least two 2D virtual representations of a given virtual kinematic device;
apply a kinematic analyzer to the input data, the kinematic analyzer being modeled with a function trained by a machine learning (ML) algorithm and the kinematic analyzer being configured to generate output data;
provide output data, the output data being data on a set of kinematic descriptors of at least one kinematic capability identified on the at least two 2D virtual representations of the given virtual kinematic device; and
determine from the output data the at least one identified kinematic capability in the given virtual kinematic device.

28. A non-transitory computer-readable medium encoded with executable instructions that, when executed, cause one or more data processing systems to:
receive input data, the input data being data on at least two 2D virtual representations of a given virtual kinematic device;
apply a kinematic analyzer to the input data, the kinematic analyzer being modeled with a function trained by a machine learning (ML) algorithm and the kinematic analyzer being configured to generate output data;
provide output data, the output data being data on a set of kinematic descriptors of at least one kinematic capability identified on the at least two 2D virtual representations of the given virtual kinematic device; and
determine from the output data the at least one identified kinematic capability in the given virtual kinematic device.

29. A data processing system, comprising:
a processor; and
an accessible memory;
wherein the data processing system is configured to:
receive input training data, the input training data being data on at least two 2D virtual representations of each of a plurality of virtual kinematic devices;
receive output training data, the output training data including, for each of the plurality of virtual kinematic devices, data on a set of kinematic descriptors on a set of kinematic capabilities of the at least two 2D virtual representations of each of the plurality of kinematic devices; wherein the output training data is related to the input training data;
train a function based on the input training data and the output training data via a machine learning (ML) algorithm; and
provide the trained function for modeling a kinematic analyzer.

30. A non-transitory computer-readable medium encoded with executable instructions that, when executed, cause one or more data processing system to:
receive input training data, the input training data being data on at least two 2D virtual representations of each of a plurality of virtual kinematic devices;
receive output training data, the output training data including, for each of the plurality of virtual kinematic devices, data on a set of kinematic descriptors on a set of kinematic capabilities of the at least two 2D virtual representations of each of the plurality of kinematic devices; wherein the output training data is related to the input training data;
train a function based on the input training data and the output training data via a machine learning (ML) algorithm; and
provide the trained function for modeling a kinematic analyzer.

31. A method for detecting, by a data processing system, a kinematic capability in a virtual kinematic device, wherein the virtual kinematic device is a virtual device having at least one kinematic capability and wherein a kinematic capability is defined by a chain with a joint connecting at least two links of the virtual device, the method comprising:
receiving input training data, the input training data being data on at least two 2D virtual representations of each of a plurality of virtual kinematic devices;
receiving output training data, the output training data including, for each of the plurality of virtual kinematic devices, data on a set of kinematic descriptors on a set of kinematic capabilities of the at least two 2D virtual representations of each of the plurality of kinematic devices; wherein the output training data is related to the input training data;
training a function based on the input training data and the output training data via a ML algorithm;
providing the trained function for modeling a kinematic analyzer.
receiving input data, the input data being data on at least two 2D virtual representations of a given virtual kinematic device;
applying the kinematic analyzer to the input data, wherein the kinematic analyzer is modeled with the function trained by a machine learning (ML) algorithm and the kinematic analyzer is configured to generate output data;
providing output data, the output data including data on a set of kinematic descriptors of at least one kinematic capability identified on the at least two 2D virtual representations of the given virtual kinematic device; and
determining from the output data the at least one identified kinematic capability in the given virtual kinematic device.
